(19) United States
(12) Patent Application Publication
(10) Pub. No.: US 2008/0268644 A1
(43) Pub. Date: Oct. 30, 2008

(54) MANUFACTURING METHOD OF SEMICONDUCTOR DEVICE AND SUBSTRATE PROCESSING APPARATUS

(75) Inventors: Kenji Kameda, Toyama-shi (JP); Naonori Akae, Toyama-shi (JP); Kenichi Suzaki, Toyama-shi (JP); Yushin Takasawa, Toyama-shi (JP); Sadao Nakashima, Toyama-shi (JP)

Correspondence Address: OLIFF & BERRIDGE, PLC, P.O. BOX 320850, ALEXANDRIA, VA, 22320-4850, US

(73) Assignee: HITACHI KOKUSAI ELECTRIC INC., Tokyo (JP)

(21) Appl. No.: 12/068,330

(22) Filed: Feb. 5, 2008

(30) Foreign Application Priority Data
Feb. 6, 2007 (JP) 2007-027064
Jan. 17, 2008 (JP) 2008-008217

(51) Int. Cl. H01L 21/306

(52) U.S. Cl. 438/694; 156/345.26; 257/E21.224; 257/E21.219

(57) ABSTRACT

There are provided the steps of loading a substrate into a reaction vessel; forming a film on the substrate while supplying a film forming gas into the reaction vessel; unloading the substrate after film formation from the reaction vessel; supplying a cleaning gas into the reaction vessel while lowering a temperature in the reaction vessel and removing a deposit deposited on at least an inner wall of the reaction vessel in the film forming step.

### BACKGROUND

1. Technical Field

The present invention relates to a manufacturing method of a semiconductor device and a substrate processing apparatus.

2. Background Art

FIG. 7 shows an example of a vertical type substrate processing apparatus for manufacturing the semiconductor device, namely, an apparatus structure of a manufacturing apparatus of the semiconductor device.

The substrate processing apparatus includes a reaction vessel 1 provided with an exhaust tube 2 as an exhaust passage, a boat 6 for disposing a plurality of substrates 3 in a processing chamber 4 formed by a reaction vessel 1, and a heater 7 installed around the reaction vessel 1 as a heating source for accelerating a thermal CVD reaction and an etching reaction. A gas supply pipe 8 for supplying a thin film source gas (called a source gas hereunder) for film formation and a gas supply pipe 9 for supplying cleaning gas for dry cleaning are connected to a lower part of the reaction vessel 1. A vacuum exhaust device 10 such as a vacuum pump is fitted to a rear stage of the exhaust pipe 2 as a pressure reducing exhaust device, and a variable conductance valve 11 is interposed on an upper stream side of the vacuum exhaust device 10.

A source gas supply pipe and a cleaning gas supply pipe may use one pipe in common. A boat 6 is supported by a seal cap 5 of a boat elevator.

When the semiconductor device is manufactured by the substrate processing apparatus thus constituted, substrate loading step of loading a substrate into a reaction vessel, film forming step of forming a film on the substrate, and substrate unloading step of unloading the substrate from the reaction vessel are executed. In the substrate loading step, a plurality of unprocessed substrates are charged into a boat 6 in multiple stages, and thereafter the boat is inserted into a processing chamber 4 by an elevation of the boat elevator. When an inside of the reaction vessel 1 is air-tightly sealed by the seal cap 5, the loading step of the substrate is ended. Next, the film forming step is executed.

In the film forming step, temperature and pressure are adjusted to the temperature and pressure suitable for substrate processing by heating of the heater 7 and exhaust of the vacuum exhaust device 10, then the source gas, being a source of a CVD thin film, is supplied to the gas supply pipe 8, and the source gas is introduced into the reaction vessel 1 from a gas inlet port 8a of the gas supply pipe 8. The source gas is deposited on a film forming surface of the substrate 3 by a thermal CVD reaction in the reaction vessel 1. When a thickness of a thin film deposited on the substrate 3 reaches a prescribed film thickness, supply of the source gas to the gas inlet port 8a is immediately stopped or intercepted to end the film forming step, and the substrate unloading step is executed. In the substrate unloading step, the boat 6 is discharged from the processing chamber 4 by lowering of the boat elevator (not shown), and the substrate 3 is discharged from the boat 6 as an already processed substrate.

Thus, in the substrate processing apparatus, the thin film of a constant film thickness is formed on a surface of the substrate by a thermal CVD reaction of the source gas. Meanwhile, a reaction product is deposited as a deposit on a part other than the substrate, namely, on an inner wall of the reaction vessel and on the surface of a component in the reaction vessel installed in the reaction vessel. In order to process a plurality of substrates, when the substrate loading step→film forming step→substrate unloading step are repeated a plurality of times as one batch, the deposit is peeled off and drops, resulting in mixing in the thin film of the substrate as a foreign matter.

Therefore, conventionally, cleaning for removing the deposit is executed for each prescribed cleaning cycle, for example, every time an accumulated thickness of the deposit reaches a prescribed value, or after single film forming processing is executed or after a plurality of number of times of the film forming processing is executed.

A conventional cleaning technique includes wet cleaning and dry cleaning.

The wet cleaning is a cleaning technique of removing the reaction vessel from a main body of the substrate processing apparatus, then cleaning it in a cleaning tank of a HF water solution, thereby removing the deposit. In using this technique, a work for removing the reaction vessel 1 from the main body of the substrate processing apparatus is necessary, thus involving a problem that a considerable time is required for returning to a state in which a film can be formed, because the reaction vessel 1 must be opened to an atmospheric air.

Therefore, in the present circumstances, the dry cleaning capable of eliminating necessity of removing the reaction vessel 1 and excellent in maintenance property is a mainstream.

A procedure of this dry cleaning will be explained, with reference to FIG. 7. First, the inside of the reaction vessel is heated by a heat of the heater 7, being a heating source, and the pressure in the reaction vessel 1 is maintained constant by a variable conductance valve 11. Thereafter, the cleaning gas is introduced into the reaction vessel 1 from a gas inlet port 9a of the gas supply pipe 9. When the cleaning gas is introduced into the reaction vessel 1, the deposit deposited on an inner face of the reaction vessel 1 becomes a gaseous reaction product and is peeled off from the surface, by an etching reaction between active species through thermal decomposition of the cleaning gas and the deposit. Such a reaction is called an etching for convenience.

When cleaning in the reaction vessel 1 by cleaning gas is ended and the deposit is discharged through the exhaust pipe 2 and the vacuum exhaust device 10, the supply of the cleaning gas to the gas inlet port 9a of the gas supply pipe 9 is stopped.

Thereafter, by a seasoning process in the reaction vessel 1, namely, by a process of replacing the cleaning gas with an inert gas, the inside of the reaction vessel 1 is recovered to a state whereby the process can be moved to the film forming step.

As described above, by the dry cleaning, the inside of the reaction vessel 1 is heated to heat the cleaning gas, thereby thermally-decomposing the cleaning gas, it is possible to generate the active species suitable for the etching reaction with the deposit to be cleaned. In addition, the deposit is also heated, and therefore heating is an important element for accelerating the etching. Further, the temperature and the etching rate has a linear relation in an arrhenius plot (graph showing a relation between the temperature and a reaction speed), and the etching rate is increased/decreased in accordance with increase/decrease of the temperature. Therefore, when the deposit is removed in a short time, preferably the temperature is raised, thereby increasing the etching rate of the cleaning gas. However, by increasing the temperature, the etching rate becomes high, resulting in deterioration of a controllability of an etching amount by adjusting a cleaning processing time, namely, a time from start of the etching to end of the etching. Therefore, even after the surface of the reaction vessel, etc, is exposed, the etching is continued, thus posing a problem that damage is generated on the surface. In order to cope with this problem, the temperature is lowered. However, a problem involved therein is that the etching rate is also lowered and the cleaning processing time is increased.

For example, the cleaning after forming a Poly Si thin film is taken as an example for explanation, as is disclosed in a patent document 1, usually, a film forming process is executed for forming the Poly Si thin film under a temperature condition of about 530 to 620° C.

When the dry cleaning process by ClF₃ gas is executed immediately after the film forming process, the temperature in the reaction vessel is immediately decreased down to a prescribed temperature, for example down to around 400° C.

When the dry cleaning is performed in a state of maintaining a high temperature beyond 500° C., this is advantageous in the point of efficiently removing the deposit by the increase of the etching rate. Meanwhile, the higher the temperature is, the more difficult to finely control the etching amount, thus making the damage on the surface large by continuing the etching even after exposing a part of the surface of the deposit and the reaction vessel and a material constituting the component in the reaction vessel installed in the reaction vessel.

In order to reduce such a damage on the surface, it is ideal to immediately stop the dry cleaning at a time point of removing the deposit. However, actually, it is difficult to uniformly remove the deposit in the reaction vessel.

[Patent document 1] Japanese Patent Laid Open Publication No. 2002-175986 (regarding the dry cleaning)

Therefore, a method of executing the dry cleaning is considered, which is executed under an intermediate condition in which the etching rate for the deposit and a protection of the surface of the reaction vessel are taken into consideration. However, in order to completely remove the deposit, over etching is necessary, which performs etching continuously even after a part of the surface of the material constituting the component in the reaction vessel is exposed. Therefore, it is difficult to reduce the damage on the surface of the reaction vessel due to accumulation of the over-etching.

### SUMMARY OF THE INVENTION

Therefore, an object of the present invention is to remove a deposit, without giving damage to an inner wall of a reaction vessel without lowering an efficiency of removing the deposit, when dry cleaning is performed.

In order to achieve the aforementioned object, a first aspect of the present invention provides the manufacturing method of the semiconductor device, including: loading the substrate into the reaction vessel; forming the film on the substrate while supplying a film forming gas into the reaction vessel; unloading the substrate after film formation from the inside of the reaction vessel; and supplying the cleaning gas into the reaction vessel and removing the deposit deposited at least on the inner wall of the reaction vessel in the film forming step.

### BRIEF DESCRIPTION OF THE DRAWINGS

FIG. 1 is an outline block diagram of a reaction furnace of a substrate processing apparatus as a semiconductor manufacturing device used suitably in an embodiment of the present invention.

FIG. 2 is a step view showing a substrate processing step and a cleaning step according to a manufacturing method of a semiconductor device of the present invention.

FIG. 3 is a step view showing a manufacturing method according to other embodiment of the present invention.

FIG. 4 is a step view showing the manufacturing method according to other embodiment of the present invention.

FIG. 5 is a view showing a temperature dependency when a Poly Si film and an SiO₂ film are subjected to etching by using a ClF₃ gas.

FIG. 6 is a view showing a pressure dependency data when the Poly Si film and the SiO₂ film are subjected to etching by using the same ClF3 gas.

FIG. 7 is a view showing an apparatus structure of a vertical-type substrate processing apparatus for manufacturing a semiconductor device.

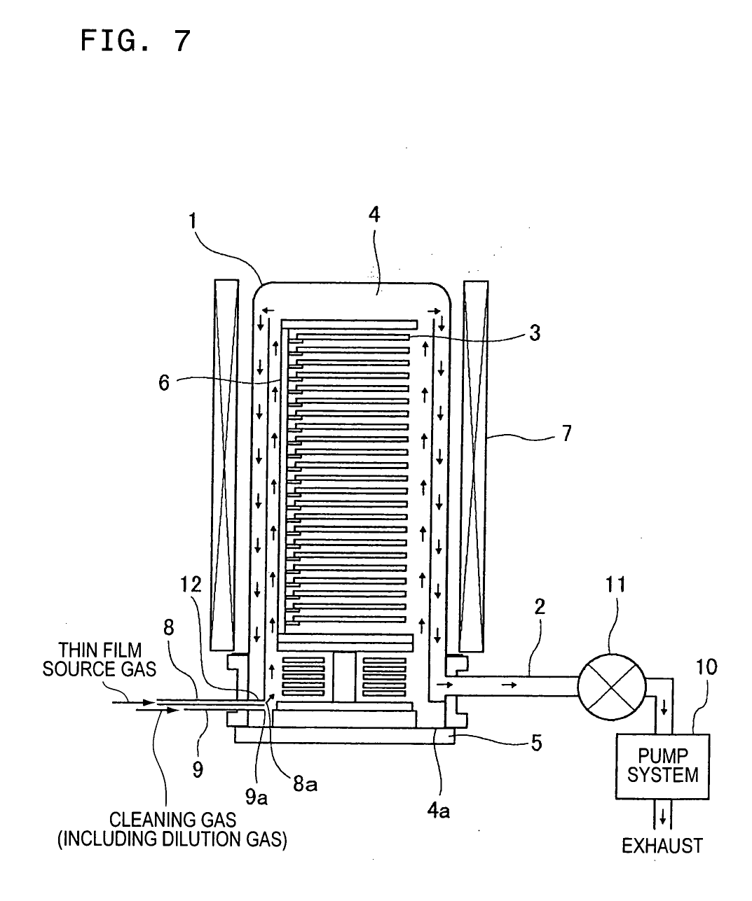

FIG. 8 is a step view showing the manufacturing method according to other embodiment of the present invention.

### DESCRIPTION OF PREFERRED EMBODIMENTS OF THE INVENTION

According to the present invention, an excellent advantage that the deposit can be removed by dry cleaning, without giving damage to the inner wall of the reaction vessel and lowering an efficiency of removing the deposit.

Preferred embodiments of the present invention will be explained, with reference to the appended drawings.

### Embodiment 1

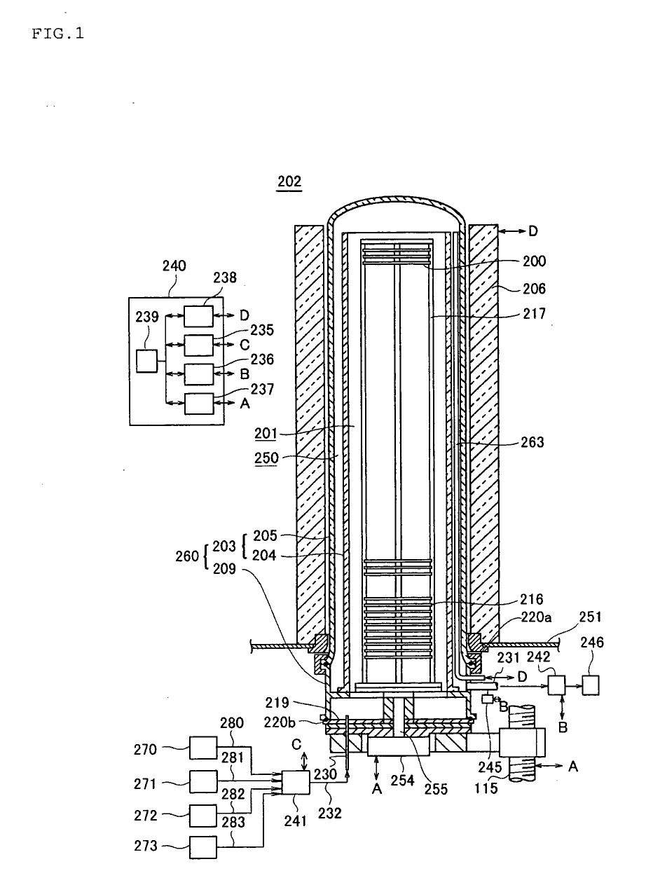

FIG. 1 is a schematic block diagram of a reaction furnace 202 of a substrate processing apparatus as a semiconductor manufacturing device suitably used in an embodiment of the present invention, and is shown as a vertical sectional view.

The reaction furnace 202 of the substrate processing apparatus has a heater 206. The heater 206 has a cylindrical shape and is vertically installed so as to surround the reaction furnace 202 by being supported by a heater base 251, being a holding plate.

A process tube 203 as a reaction tube is disposed concentrically with the heater 206.

The process tube 203 is constituted of an inner tube 204 as an internal reaction tube, and an outer tube 205 as an external reaction tube provided outside of the inner tube 204.

The inner tube 204 is made of a heat resistant material such as quartz (SiO₂) or silicon carbide (SiC), etc, and is formed in a cylinder shape, with an upper end and a lower end opened.

A processing chamber 201 is formed in a cylindrical hollow part of the inner tube 204, so that wafers 200 as substrates can be stored in a state of being arranged in multiple stages horizontally in a vertical direction by a boat 217 as will be described later.

The outer tube 205 is made of the heat resistant material such as quartz or silicon carbide, and is formed in the cylinder shape, with an inner diameter made larger than an outer diameter of the inner tube 204 and the upper end closed and the lower end opened, and is provided concentrically with the inner tube 204.

A manifold 209 is disposed below the outer tube 205 concentrically with the outer tube 205.

The manifold 209 is, for example, made of stainless, etc, and is formed in the cylinder shape, with the upper end and the lower end opened.

The manifold 209 is engaged with the inner tube 204 and the outer tube 205, so as to support them. Note that an O-ring 220a is provided between the manifold 209 and the outer tube 205 as a sealing member.

By supporting the manifold 209 by the heater base 251, the process tube 203 is set in a state of being vertically installed.

The manifold 209 is connected to the process tube 203 and a reaction vessel 260 is thereby formed.

A nozzle 230 as a gas inlet unit is connected to a seal cap 219 as will be described later so as to communicate with a lower part in the reaction vessel 260, and a gas supply pipe 232 is connected to the nozzle 230. A source gas supply source 270 coupled to a source gas supply line 280, a cleaning gas supply source 271 coupled to a cleaning gas supply line 281, an inert gas supply source 272 coupled to an inert gas supply line 282, and a hydrogen gas supply source 273 coupled to a hydrogen gas supply line 283 used in an embodiment 4 as will be described later are connected to an upper stream side of the gas supply pipe 232, being an opposite side to a connection side of the nozzle 230.

A gas supply amount controller 235 is electrically connected to the MFC 241, to control a gas flow rate at a desired timing so as to be a desired amount. Note that in FIG. 1, the MFC 241 common in all line is shown for convenience, instead of originally using one MFC 241 in one line.

An exhaust tube 231 for exhausting an atmosphere in the reaction vessel 260 is disposed in the manifold 209.

The exhaust tube 231 is disposed in a lower end part of a cylindrical space 250 formed by a gap between the inner tube 204 and the outer tube 205, so as to be communicated with the cylindrical space 250.

A vacuum exhaust device 246 such as a vacuum pump is connected to a lower stream side of the exhaust tube 231, being the opposite side of the connection side to the manifold 209, via a pressure sensor 245 as a pressure detector unit and a pressure adjustment device 242, so that the inside of the reaction vessel 260 is vacuum-exhausted to set a pressure in the reaction vessel 260 in a prescribed pressure, namely, in a vacuum state.

A pressure controller 236 is electrically connected to the pressure adjustment device 242 and the pressure sensor 245, so as to control the pressure in the reaction vessel 260 at a desired timing to become a desired pressure by the pressure adjustment device 242 based on the pressure detected by the pressure sensor 245.

The seal cap 219 is disposed in a lower part of the manifold 209, as a throat lid member capable of air-tightly closing a lower end opening of the manifold 209, namely, a throat.

The seal cap 219 is brought into contact with the lower end of the manifold 209 from vertically lower side.

The seal cap 219 is made of metal such as stainless, and is formed in a disc shape. An O-ring 220b as a seal member that is brought into contact with the lower end of the manifold 209 is disposed on an upper surface of the seal cap 219.

A rotating mechanism 254 for rotating the boat 217 is installed on the opposite side to the processing chamber 201 of the seal cap 219. A rotating shaft 255 of the rotating mechanism 254 penetrates the seal cap 219 and is connected to the boat 217 as will be described later, so that a substrate 200 is rotated by rotating the boat 217.

The seal cap 219 is vertically elevated by a boat elevator 115 as an elevating mechanism which is vertically installed outside of the process tube 203. Thus, the boat 217 can be loaded/unloaded into/from the processing chamber 201.

A drive controller 237 is electrically connected to the rotating mechanism 254 and the boat elevator 115, so that a desired operation is controlled at a desired timing.

The boat 217 as a substrate holding tool is composed of heat resistant materials containing Si such as quartz (SiO₂) and a silicon carbide (SiC), so as to hold a plurality of substrates 200 in a horizontal posture in multiple stages, with centers thereof mutually aligned. Note that a plurality of heat insulating plates 216 as a heat insulating member having a disc shape made of heat resistant material such as quartz and silicon carbide are disposed in multiple stages in a horizontal posture, so that a heat from the heater 206 is hardly transmitted to the side of the manifold 209.

A temperature sensor 263 as a temperature detector unit is installed in the process tube 203. A temperature controller 238 is electrically connected to the heater 206 and the temperature sensor 263. By adjusting a power supply condition to the heater 206 based on temperature information detected by the temperature sensor 263, the temperature in the reaction vessel 260 is controlled at a desired timing, so as to have a desired temperature distribution.

The gas supply amount controller 235, the pressure controller 236, the drive controller 237, and the temperature controller 238 constitute an operation part and the input/output part also, and are electrically connected to a main controller 239 that controls an entire body of the substrate processing apparatus. These gas supply amount controller 235, pressure controller 236, drive controller 237, temperature controller 238, and main controller 239 are constituted as a controller 240.

Next, explanation will be given for the manufacturing method of the semiconductor device for forming a CVD film, for example, the thin film such as a Poly Si thin film by using the reaction furnace 202 according to the aforementioned structure. In addition, in an explanation hereunder, an operation of each part of the substrate processing apparatus is controlled by a controller 240.

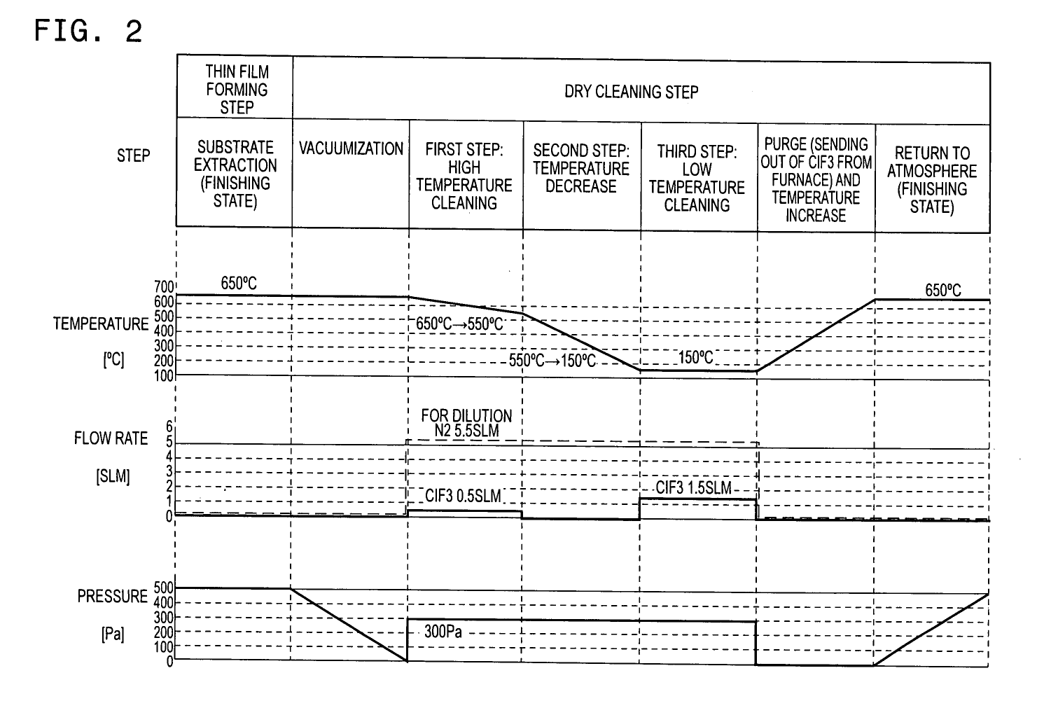

FIG. 2 is a step view showing a substrate processing step and a cleaning step according to the manufacturing method of the semiconductor device of the present invention. Note that the cleaning step is executed at a prescribed cleaning cycle, for example, after a single or a plurality of film forming steps are repeated and before the next thin film forming step is executed.

In FIG. 2, in the thin film forming step, the substrate loading step, being the step of loading the substrate 200 into the processing chamber 201, the film forming step, being the step of supplying a film forming gas into the reaction vessel while heating the inside of the reaction vessel at a first temperature, and the substrate unloading step, being the step of unloading the substrate 200 after film formation from the inside of the reaction vessel, are sequentially executed. In addition, in the dry cleaning step, a vacuumization step, a first removing step, namely a high temperature cleaning step as a first cleaning step, the step of decreasing the temperature, a second removing step, namely a low temperature cleaning step as a second cleaning step, a purge and temperature increasing step, and an atmosphere returning step for the next thin film forming step are sequentially executed. Each step will be explained hereunder, with reference to FIG. 1 and FIG. 2, in an order of steps.

### <Boat Loading Step (Loading Step of the Substrate)>

In this step, a plurality of substrates 200 are loaded, namely, wafer-charged into the boat 217. In this step, the inside of the reaction vessel 260 is set at a substrate loading temperature.

Next, this boat 217 is loaded into the processing chamber 201 (boat loading) by the elevation of the boat elevator 115. When the loading of the boat 217 is ended, the manifold 209 is sealed by the seal cap 219 of the boat elevator 115 via the O-ring 220b, thus sealing the reaction vessel 1 in a state of being intercepted from outside.

Thereafter, the atmosphere in the reaction vessel 260 is exhausted by the vacuum exhaust device 246, and the pressure in the reaction vessel 260 is adjusted to be a prescribed pressure, namely, a vacuum state, preferably to be vacuum, by a feedback control of the pressure adjustment device 242 based on the pressure detected by the pressure sensor 245 for detecting the pressure.

In addition, based on the temperature information detected by the temperature sensor 263, the power supply condition to the heater 206 is feedback-controlled, so that the inside of the reaction vessel 260 has a prescribed temperature distribution, based on the temperature information detected by the temperature sensor 263. Subsequently, the substrate 200 is rotated by rotating the boat 217 by the rotating mechanism 254.

When the temperature and the pressure in the reaction vessel 260 are respectively stabilized to be the temperature and the pressure suitable for film formation as the thin film, the film forming step is executed.

### <Film Forming Step>

In the film forming step, the source gas as a film forming gas is supplied to the gas supply pipe 232 from the source gas supply source 270 through the source gas supply line 280. When the thin film such as the Poly Si thin film is formed on the substrate 200, being a silicon wafer, SiH₄ is used for the source gas. At this time, the flow rate of the source gas is feedback-controlled by the MFC 241 so as to reach a prescribed flow rate. The source gas is introduced into the nozzle 230 from the gas supply pipe 232, and is introduced into the reaction vessel 260 from a gas supply port of the nozzle 230.

Then, the source gas is moved upward in the reaction vessel 260 and is brought into contact with the surface of the substrate 200 at the time of passing through the processing chamber 201, and is deposited on the surface of the substrate 200 by thermal CVD reaction. Remaining source gas is flown out to the cylindrical space 250 from the upper end opening of the inner tube 204 and is discharged by the exhaust tube 231.
Note that as film forming conditions for the Poly Si film:
Processing temperature: 530° C. to 650° C.
Pressure in the reaction vessel: around 0 to 1000 Pa
Source gas: SiH₄ (several tens ccm to several thousands ccm (litter/min))
   are taken as examples.

When a film formation processing time required for forming the thin film such as Poly Si thin film on the surface of the substrate 200 is elapsed, the supply of the source gas to the gas supply pipe 232 from the source gas supply source 270 is stopped or intercepted, and the inert gas such as N₂, Ar, He is supplied as a purge gas to the gas supply pipe 232 from the inert gas supply source 272 through the inert gas supply line 282. The purge gas is introduced to the nozzle 230 from the gas supply pipe 232, and is introduced into the reaction vessel 260 from the gas supply port of the nozzle 230, specifically into the reaction vessel 260 through the manifold 209.

Similarly to a case of the source gas, the purge gas move upward in the reaction vessel 260 and is flown out to the cylindrical space 250 between the inner tube 204 and the outer tube 205 from the upper end opening of the inner tube 204 and is exhausted from the exhaust tube 231. The inside of the reaction vessel 260 is returned to a normal pressure by being replaced with this inert gas atmosphere.

When the film forming step is ended, the unloading step of the substrate is executed.

### <Boat Unloading Step (Unloading Step of the Substrate)>

In the unloading step of the substrate, the throat of the manifold 209 is opened by lowering of the seal cap 219 due to lowering of the boat elevator 115, an already processed substrate 200 is unloaded to the outside of the process tube 203 from the lower end of the manifold 209 in a state of being supported by the boat 217 (boat unloading). Thereafter, the already processed substrate 200 is taken out, namely wafer-discharged from the boat 217.

### <Dry Cleaning Step>

When the cleaning cycle of the deposit arrives, the cleaning gas and dilution gas are introduced into the reaction vessel 260 in the step between the dry cleaning step an the next thin film forming step, and the dry cleaning of the deposit by the cleaning gas of a prescribed volume concentration is executed. The cleaning gas at this time preferably contains fluorine atom (F) and chlorine atom (Cl) in bonding. Particularly, chlorine (Cl₂), chlorine fluoride based gas, chlorine trifluoride (ClF₃) or fluorine (F₂) and hydrogen fluoride (HF) having a moderate reactivity even in a low temperature region are preferable. Note that when the deposit is the Poly Si film, the gas containing the chlorine fluoride based gas, the chlorine trifluoride (ClF₃) or the fluorine (F₂) is used as the cleaning gas.

The inert gas such as N₂, Ar, He is used as the dilution gas for diluting the cleaning gas.

In the dry cleaning step, the high temperature cleaning step as a first step of cleaning, the temperature decreasing step as a second step of cleaning, the low temperature cleaning step as a third step of cleaning, the purge and temperature increasing step for exhausting the atmosphere after cleaning, and the atmosphere returning step for the next thin film forming step are sequentially executed after the vacuumization step.

### <Vacuumization Step>

In the vacuumization step, the atmosphere in the reaction vessel 260 is exhausted by the vacuum exhaust device 246 while maintaining the temperature in the reaction vessel 260 to 500° C. or more, by heating using the heater 206, in a state that the throat of the manifold 209 is sealed by the seal cap 219 and the O-ring 200b of the boat elevator 115.

At this time, the pressure in the reaction vessel 260 is set in a vacuum (in the vicinity of 0 Pa to 5 Pa).

### <First Cleaning Step (High Temperature Cleaning Step)>

A cleaning method used in the first removing step, namely in the first cleaning step (high temperature cleaning step) includes a method of cleaning (first cleaning method) by introducing the cleaning gas into the reaction vessel 260 while decreasing the temperature in the reaction vessel 260 from the first temperature to a high temperature which is lower than this first temperature, and a method of cleaning (second cleaning method) by introducing the cleaning gas into the reaction vessel 260 while maintaining the temperature of the reaction vessel 260 to a constant high temperature. Note that even if either one of the methods is selected, the pressure in the reaction vessel is maintained in a reduced pressure state to perform cleaning.

The first cleaning method will be explained hereunder by each method. In a case of the first cleaning method, first, by decreasing the temperature of the heater 206 and cooling the inside of the reaction vessel 260, the cleaning gas is introduced into the reaction vessel 260 while gradually decreasing the temperature from a first temperature (the same temperature as the temperature of the vacuumization step and the same temperature as the temperature of the vacuumization step and the boat unloading step) to a second temperature (temperature exceeding 500° C.) which is lower than the first temperature. Note that the temperature of the reaction vessel 260 at the time of the boat unloading step is set as a substrate unloading temperature.

In this case, the cleaning gas is supplied to the gas supply pipe 232 from the cleaning gas supply source 271, via the cleaning gas supply line 281 and the MFC 241, and the cleaning gas is introduced into the reaction vessel 260 from the gas inlet port of the nozzle 230. A cleaning processing time by introducing the cleaning gas is decided so that a thickness of the deposit at the time of ending the cleaning reaches a target etching amount, based on the etching rate of the cleaning gas at each temperature at the time of decreasing the temperature from the first temperature to the second temperature and an original thickness of the deposit deposited on the inner wall of the reaction vessel 260 and the surface of the component in the reaction vessel 260. Note that in the embodiment 1, the MFC 241, the gas supply pipe 232, and the nozzle 230 are used in common for the source gas and the cleaning gas. However, they may be provided separately in accordance with the kind of the gas.

Preferably, the target etching amount is set at, for example, around 90%, which is at least half or more of an original thickness of the deposit and under the original thickness of the deposit.

Note that when the temperature of the inside of the furnace is decreased in a state of depositing a reaction product in the reaction vessel, a crack occurs to the deposit and the deposit is peeled off from the inside of the reaction vessel, thus generating particles from the deposit. Therefore, when the temperature is decreased in a state of placing the substrate in the reaction vessel, the generated particles are deposited on the substrate. However, the temperature is decreased in the cleaning step which is a state of not placing the substrate in the reaction vessel, and therefore even if the particles are generated, the problem of depositing the particles on the substrate does not occur.

Also, by decreasing the temperature, the crack is generated in the deposit by a thermal stress to the deposit. Thus, a surface area of the deposit, namely, an area brought into contact with the cleaning gas can be made large. Therefore, the etching rate and the cleaning speed as a speed of removing the deposit can be made increased.

As described above, when the cleaning gas is introduced while decreasing the temperature, the etching rate of the cleaning gas is gradually decreased corresponding to a temperature gradient of a temperature decrease, namely, the etching rate becomes maximum at a first temperature which is a high temperature, and the etching rate becomes minimum at a second temperature, and the etching rate of the cleaning gas changes from maximum to minimum between the first temperature and the second temperature. Note that in an entire body of this specification, the “etching rate is gradually decreased” includes a case that the temperature is set to be constant for a prescribed period from the first temperature to the second temperature.

When the etching rate is thus changed following after the change of the temperature, etching of a large etching amount to the deposit is performed for a short period at the first temperature side, and the etching of small etching amount and capable of controlling the etching amount is performed at the second temperature side. Namely, the speed of removing the deposit becomes larger at a higher temperature and becomes smaller at a lower temperature. However, when the cleaning gas is continued to be supplied while lowering the temperature, the deposit can be roughly cut and removed by increasing the removing speed at the high temperature, thus making it possible to finely remove the deposit by gradually making the removing speed small, as the temperature is lowered.

Accordingly, according to the first method, the etching of a large etching amount that gives priority to shortening of the etching time is performed at the first temperature side, and the etching of a small etching amount capable of controlling the etching amount by setting a processing time is performed at the second temperature side, and as a result, the deposit can be accurately etched to a target etching amount at a shorter time than conventional.

Therefore, it is possible to end the first cleaning step in a state of no over etching of the inner surface of the reaction vessel 260, specifically inner/outer surfaces of the inner tube 204, the inner surface of the outer tube 205, the inner surface of the manifold 209, and the outer surface of the boat 217.

Accordingly, even if the inner wall of the reaction vessel 260 and a component arranged in the reaction vessel is constituted of the Si material containing Si, such as quartz (SiO₂), the surface is not exposed to the cleaning gas, and damage does not occur to the surface by over etching. Namely, the deposit can be removed without etching a constituent component of the reaction furnace such as a reaction tube as much as possible.

Thus, in the first cleaning step (high temperature cleaning step), the etching of a prescribed amount can be applied to the deposit for a short time by using a relation between the temperature and the etching rate.

In addition, the temperature decrease is started, with the first temperature set as the same temperature as the temperature of the vacuumization step or the same temperature as the temperature of the boat unloading step, and the cleaning gas is introduced into the reaction vessel 60, thereby making it possible to improve a throughput, because the etching can be performed without providing a useless time for decreasing the temperature.

Next, explanation will be given for the second cleaning method in the first cleaning step (high temperature cleaning step).

In this second cleaning method, first, the cleaning gas is supplied to the gas supply pipe 232 form the cleaning gas supply source while maintaining the temperature in the reaction vessel 260 at 550° C. or more by a temperature control of the heater 206, and the cleaning gas is introduced into the reaction vessel 260 from the gas inlet port of the nozzle 230, and as a result, half or more, under whole thickness, for example 90% or more of the deposit deposited on the reaction vessel or the inside component of the reaction vessel arranged in the reaction vessel 260, specifically the inner wall of the inner tube 204, the outer tube 205, the manifold 209 and the outer surface of the boat 217 can be removed.

In this case, similarly to a case of the first method, the cleaning processing time by the etching of the cleaning gas is calculated based on the thickness of an original deposit before etching deposited on the surface of the inner wall of the reaction vessel 260 and the component arranged in the reaction vessel, the etching rate of the cleaning gas at the temperature exceeding 500° C., preferably at the temperature of 550° C., and is decided so that a final etching amount to the deposit is half or more and under the whole thickness of the deposit, for example, around 90%. However, the etching rate of the cleaning gas becomes higher as the temperature becomes higher, and a case that the etching amount by setting the cleaning processing time is hardly controlled is estimated.

Therefore, in this second cleaning method, the etching rate of the cleaning gas is adjusted so as to correspond to the cleaning processing temperature, namely, the etching rate at 550° C. in this example.

An adjustment method of the etching rate of the etching gas includes a method of adjusting a total pressure of the cleaning gas to the reaction vessel 260, namely a method of adjusting a supply pressure of the cleaning gas to the reaction vessel 260, and a method of lowering a partial pressure of the cleaning gas by diluting the cleaning gas with a dilution gas composed of inert gas (N₂, Ar, He, etc). However, in order to perform a total and uniform etching, the latter method is more preferable in which the cleaning gas is diluted with the dilution gas composed of the inert gas to lower the partial pressure to the dilution gas.

Therefore, in the second method, as a result of studying on the cleaning gas having a good controllability suitable for the etching at a high temperature exceeding 500° C., it is found that the aforementioned condition is satisfied when a volume concentration of the cleaning gas is 1 vol % or more and under 10 vol %. In this case, the volume concentration of the cleaning gas is more preferably set in a range from 1 vol % or more and 5 vol % or less.

Therefore, the second cleaning method provides the method of etching the deposit by introducing the cleaning gas to the reaction vessel 260 while maintaining the temperature in the reaction vessel 260 to a temperature exceeding 500° C. and to a constant temperature, wherein by using the cleaning gas having the volume concentration of 1 vol % or more and under 10 vol %, the etching processing time is defined, so that at least half or more of the original thickness of the deposit and under the original thickness of the deposit, for example around 90% can be etched.

When the etching rate is thus adjusted, the controllability of the etching amount according to time is stabilized. Therefore, even when the inner wall of the reaction vessel 260 and the component arranged in the reaction vessel are constituted of the Si material containing Si, such as quartz (SiO₂) and silicon carbide (SiC), namely, generation of the damage by etching is prevented on the boundary surface with the deposit, thus making it possible to significantly reduce the cleaning processing time.

Note that the cleaning gas with the volume concentration of 1 vol % or more and under 10 vol % may also be used in the first cleaning method.

Note that in the first cleaning step, when the deposit is Poly Si, the first temperature is set at 530° C. to 620 (the temperature exceeding 500° C.), and the second temperature is set at the temperature just before 500° C., and in a case of Si₃N₄, the first temperature is set at 720° C., and the second temperature is set at the temperature just before 550° C. In each case, the aforementioned cleaning is performed while gradually lowering the temperature from 530° C.-620 (500° C. or more) to the temperature just before 500° C., namely, form 720° C. to 550° C.

In addition, in the first cleaning method of the first cleaning step, an aspect for “the temperature is gradually decreased from the first temperature to the second temperature” includes both aspects of a case that the etching rate is made large on the temperature gradient side and a case that the etching rate is made small on the second temperature gradient side.

In addition, in the cleaning processing time, the controllability of the etching amount according to time may be improved, with the temperature just before the second temperature is set as the temperature of a finish time of the cleaning.

### <Temperature Lowering Step>

In this step, the temperature in the reaction vessel 260 is gradually lowered to the temperature at the time of finishing the first cleaning step, namely, from the second temperature exceeding 500° C. to the temperature under 200° C., preferably to the temperature under 200° C. and 150° C. or more, more preferably to the third temperature of 150° C. Such a temperature lowering step corresponds to a temperature transition time for moving to the next low temperature cleaning step in which the cleaning is performed at the temperature under 200° C., and the deposit in the reaction vessel 260 is not removed I this step. Therefore, the temperature is lowered at a constant temperature gradient, and during this temperature lowering step, a vaporized deposit generate in the first cleaning step is exhausted while introducing the only the inert gas and introduction of the cleaning gas is stopped.

Note that in this step, when a residual amount of the deposit can be accurately detected, the cleaning gas of a smaller amount than the amount flown in the first cleaning step is introduced while gradually lowering the temperature in this temperature lowering step, and a residual film may be gradually removed, so that the inner wall of the reaction vessel 260 and the surface of the component arranged in the reaction vessel are not exposed.

When the residual film after the first cleaning step is thinly etched in the temperature lowering step, the thickness of the residual film removed in the next low temperature cleaning step is made thin, and therefore a cleaning time as an entire body can be made shortened.

### <Second Cleaning Step (Low Temperature Cleaning Step)>

In the second removing step, namely, in the second cleaning step (low temperature cleaning step), the temperature in the reaction vessel 260 is maintained to a prescribed temperature in a temperature range of a low temperature from under 200° C. to 100° C. or more so that the temperature in the reaction vessel 260 becomes a lower temperature than the temperature at the time of the first cleaning step. Then, the cleaning processing time is calculated so that only the residual film can be etched, based on the thickness of the deposit, namely, the thickness of the residual film of the deposit after the first cleaning step, and the etching rate at the temperature set in the temperature range of the low temperature from under 200° C. to 100° C. or more. The cleaning gas is introduced into the reaction vessel 260 from the gas inlet port of the nozzle 230 during such a cleaning processing time.

The thickness of the residual film is sufficiently made small by the cleaning in the first cleaning step. The etching rate of the temperature set in the low temperature cleaning step is lower than the etching rate in the first cleaning step respectively, and the etching amount is made smaller. Therefore, by the etching, the inner wall of the quartz of the reaction vessel 260 is not exposed, thus giving no damage by etching.

As a result, the residual film of the deposit deposited on the inner wall of the reaction vessel 260 and the component arranged in the reaction vessel, namely, the residual film after the first cleaning step is removed. Namely, in a case of the low temperature cleaning step (under 200° C. and 100° C. or more), a good etching selectivity of the residual film and a quartz inner wall is obtained, and therefore a small damage only occurs to the inner wall of the quartz, even if the inner wall of the quartz is exposed to the cleaning gas.

In addition, when the inert gas is introduced as the dilution gas into the reaction vessel 260 at a prescribed temperature in a temperature range of under 200° C. and 100° C. or more, the etching rate of the cleaning gas is further lowered. Therefore, there is no damage given to the surfaces of the inner wall of the reaction vessel 260 and component in the reaction vessel 260. Further, the residual film of the deposit can be removed without allowing the residual film to be remained at a practical etching rate.

Note that when the temperature in the reaction vessel 260 is set at under 200° C. and 100° C. or more, this is suitable for etching when both of shortening of the cleaning processing time and accuracy of the etching amount are required.

In addition, in this case, by gradually increasing the volume concentration of the cleaning gas, gradually increasing a gas partial pressure, and gradually increasing a gas total pressure, the controllability of the etching rate can be improved. At this time, by increasing the gas partial pressure, the volume concentration of the cleaning gas can be increased, with the total pressure set to be constant. In addition, by increasing the gas total pressure, the total pressure can be increased, with the volume concentration of the cleaning gas set to be constant.

### <Purging and Temperature Increasing Step>

When the second cleaning step (low temperature cleaning step) is finished, the supply of the cleaning gas to the gas supply pipe is immediately stopped or intercepted. Then, the temperature in the reaction vessel 260 is gradually increased so as to be a processing temperature, preferably 650° C. by heating of the heater 206 by the temperature sensor and the temperature controller.

When the inside of the reaction vessel 260 is exhausted while gradually increasing the temperature of the reaction vessel 260 to the processing temperature, the vaporized reaction product can be discharged, with no reaction product remained. Therefore, cleaning of the reaction vessel 260 can be achieved.

### <Atmospheric Returning Step (Finish State)>

In this step, the temperature in the reaction vessel 260 is maintained to the processing temperature (500 to 650° C.) by temperature control of the heater 206, and the step is finished at the time point when the pressure is returned to the atmospheric pressure by exhaustion.

When this step is finished, a thin film forming step explained previously as the next batch processing step is started.

Thus, in the dry cleaning according to this embodiment 1, first, by performing dry cleaning (high temperature cleaning step) under a high temperature condition, a major part of the deposit deposited on the inner wall of the reaction vessel 260 and the component in the reaction vessel 260 is removed. Next, by performing dry cleaning (a low temperature cleaning step) under a low temperature condition, the residual film of the remained deposit can be completely removed, in a state of maintaining the selectivity from the surface of the material such as quartz constituting the reaction vessel 260 and the component in the reaction vessel 260. Thus, the damage of the surface of the material due to cleaning gas can be reduced and also the cleaning time can be shortened.

Next, an example in the embodiment 1 of the present invention will be explained, with reference to FIG. 1 and FIG. 2.

FIG. 2 is a step view of a manufacturing method according to this example.

Note that the inner wall of the reaction vessel 260 of the substrate processing apparatus, being a manufacturing device of the semiconductor device according to this example is constituted of quartz (SiO₂) or SiC.

As a first step, the cleaning gas is diluted with N2 gas and is introduced into the reaction vessel 260 under a high temperature condition of 650° C., being the same temperature as the processing temperature, so that the volume concentration of ClF₃ gas reaches 5 vol %. Then, the dry cleaning under the high temperature is started while maintaining the gas flow rate to the reaction vessel 260 and the pressure of the reaction vessel 260, and the dry cleaning is continued while the temperature is decreased at a constant ratio just before reaching the point from 650° C. to 500° C. (550° C. in this case). In this case, the ClF₃ gas as the cleaning gas is similarly supplied from different gas supply pipes to mutually independent different nozzles to similarly different nozzles, and is introduced to the reaction vessel 260 from the nozzle.

In addition, the cleaning processing time is set as a time capable of removing 90% of the deposit based on the etching rate of the cleaning gas at each temperature, when the temperature is decreased in the reaction vessel 260.

Next, as the second step, the introduction of the ClF₃ gas is stopped and the temperature in the reaction vessel 260 is decreased down to 150° C. from around 500° C. (550° C. in this case) in an N₂ gas atmosphere, being inert gas.

Subsequently, as the third step, the cleaning gas is diluted with the N₂ gas under the low temperature condition of 150° C., so that the volume concentration of the ClF₃ gas reaches 25 vol %, and the dry cleaning is executed under the low temperature condition in a reduced pressure state while maintaining the gas flow rate and the pressure.

At this time, the cleaning processing time is set as the time capable of completely removing the deposit based on the thickness of the residual film of the deposit that has undergone etching in the first step and the etching rate of the cleaning gas at the temperature of 150° C., and the over etching is assumed.

Thus, in the first step, namely in the high temperature cleaning step, 90% of the deposit is removed and 10% of the deposit stays deposited as the residual film. However, in the third step, namely in the low temperature cleaning step, all of the deposits are removed. In this case, the over etching processing time is assumed in the cleaning processing time, so as to finish the cleaning at 150° C. However, this is the etching at a low temperature (150° C.) and the etching rate is low. Therefore, the damage of the reaction vessel made of quartz, namely the damage on the surface of the inner wall of the inner tube 204 and the outer tube 205 due to etching is extremely small.

In addition, a required time of cleaning from the first step to the third step is also extremely small, thus making it possible to improve the throughput.

Accordingly, the over etching is assumed in the etching of the deposit, and even when the dry cleaning is repeated for every one or a plurality of cleaning cycles, an accumulative damage on the surface of an Si-containing material is extremely small compared to conventional.

Note that when the volume concentration of the cleaning gas is adjusted, the cleaning gas and the dilution gas may be introduced into the reaction Bessel 260 by separate piping respectively, or the cleaning gas, with the volume concentration adjusted, may be introduced from one nozzle.

In addition, when the cleaning processing time is decided at two temperatures of high temperature (first temperature) and low temperature (second temperature), the timing may be corrected so as to finish the cleaning processing at the temperature immediately before finishing the cleaning processing time for preventing the over etching.

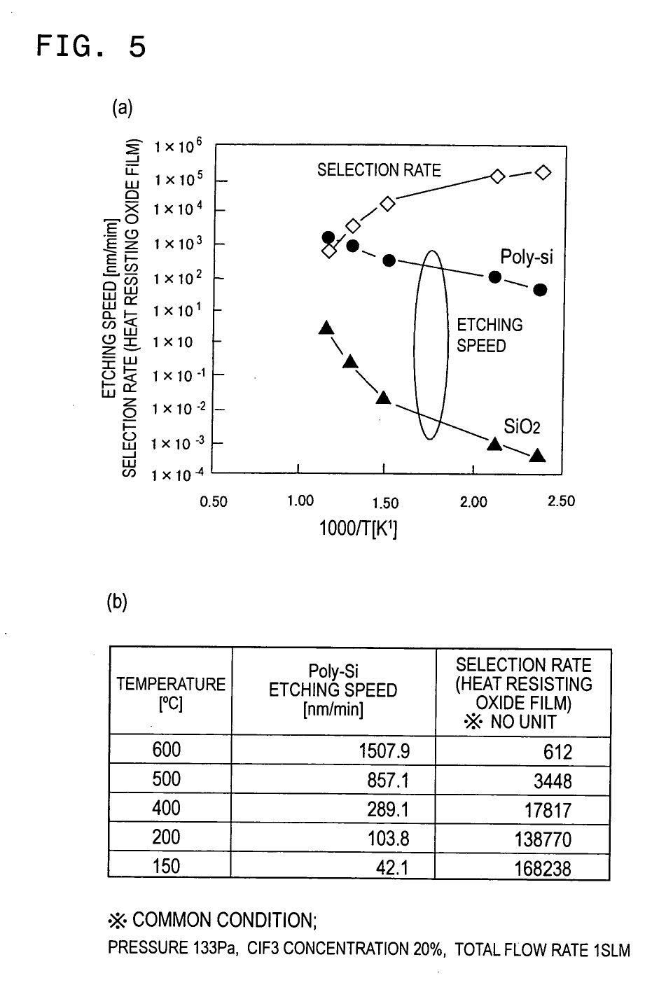

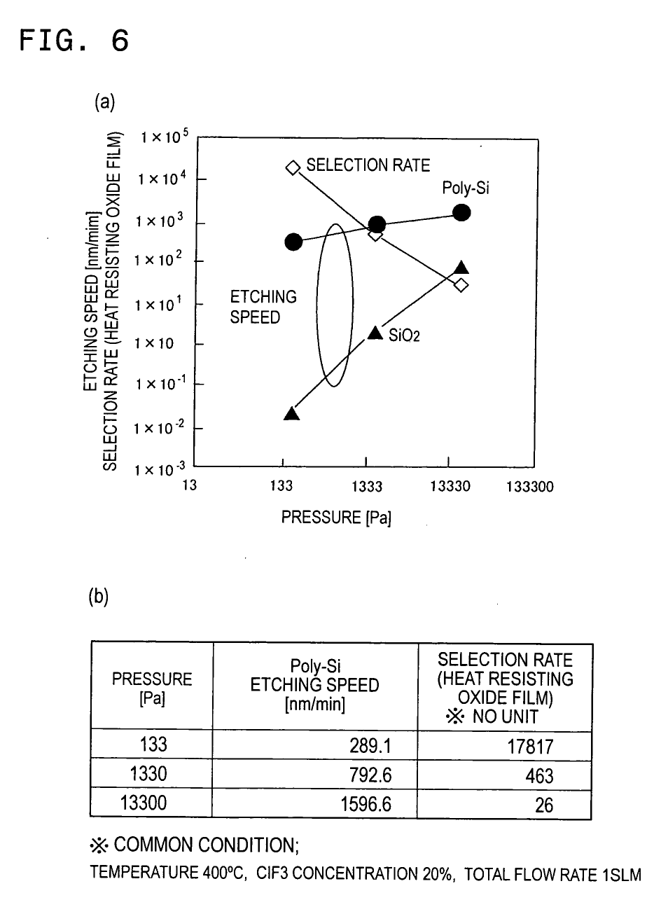

FIG. 5A and FIG. 5B show a temperature dependency at the time of etching the Poly Si film and a thermal oxide film formed by thermal CVD reaction by using the ClF₃ gas, and FIGS. 6A and 6B show pressure dependency data at the time of etching the Poly Si film and the thermal oxide film by similarly using the ClF₃ gas.

As shown in FIG. 5A and FIG. 5B, the temperature dependency of the etching rate is observed in the Poly Si film, and although the etching rate is higher along with the increase of the temperature, a selection rate to the thermal oxide film (=Poly Si/SiO2) is prone to be lowered.

Meanwhile, under a low temperature condition of 200° C. or less, although the etching rate of the Poly Si film is slightly lowered, a practical value is obtained, and also an extremely high selection rate to the thermal oxide film can be secured.

Further, as shown in FIGS. 6A and 6B, even in case of the same condition, the etching rate of the Poly Si film can be suppressed by lowering the partial pressure of the ClF₃ gas as the cleaning gas, and also the selectivity of the thermal oxide film can be significantly improved.

Accordingly, based on the aforementioned experiment data, if the dry cleaning under the high temperature condition (high temperature cleaning step) and the dry cleaning under the low temperature condition (low temperature cleaning) are combined, it is found that generation of the damage on the surface can be suppressed or suppressed to minimum even if the inner wall of the reaction vessel 260 and the component in the reaction vessel 260 is constituted of a material prone to be damaged on the surface, namely is constituted of a Si containing material such as SiO₂ (quartz) and SiC (silicon carbide).

Note that although the ClF₃ gas has been typically explained, the same thing can be said for the gas containing fluorine atom (F) and chlorine atom (Cl) in a bond, such as chlorine (Cl2), chlorine fluoride based gas, fluorine (F₂), and hydrogen fluoride (HF).

Explanation will be given for other embodiment of the manufacturing method of the semiconductor device according to the present invention.

### Embodiment 2

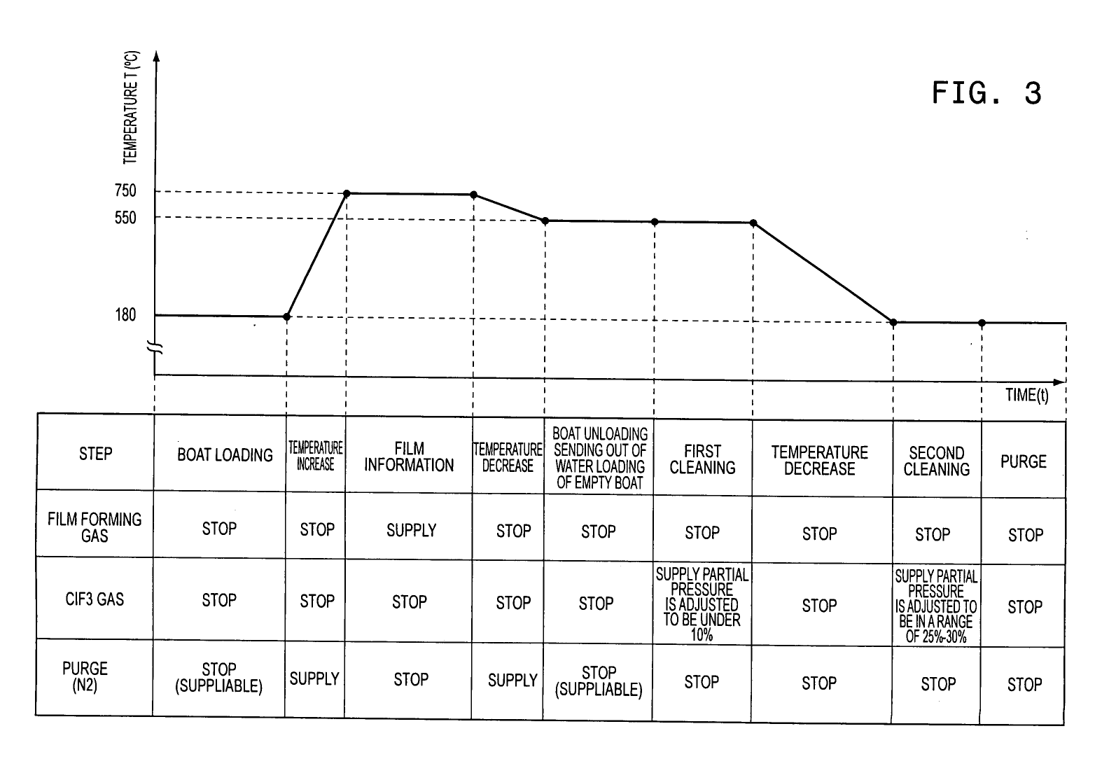

FIG. 3 is a step view showing the manufacturing method. In this embodiment also, similarly to the embodiment 1, the dry cleaning step for removing the film of the deposit is executed between this step and the next thin film forming step after the film forming step of once or a plurality of number of times are repeated. In addition, in the dry cleaning step, the cleaning gas similar to the cleaning gas of the embodiment 1 is used, and for example, the cleaning gas containing the ClF₃ gas or the fluorine (F) is used, and as the dilution gas of the cleaning gas, the inactive gas such as N2, Ar, and He is used.

In the manufacturing method according to an embodiment 2, the boat loading step, the temperature increasing step in the reaction vessel, the film forming step, the temperature decreasing step in the reaction vessel, the boat unloading, discharge of the substrate, the loading step of an empty boat 217, the first cleaning step (high temperature cleaning step), the temperature decreasing step in the reaction vessel, the second cleaning step (low temperature cleaning step), and a purging step are sequentially executed.

Each step will be explained in an order of the step, with reference to FIG. 1 and FIG. 3.

### <Boat Loading Step>

In the boat loading step, the pressure in the reaction vessel 260 is feedback-controlled by the pressure sensor 245 and the pressure adjustment device 242, and an atmosphere temperature in the reaction vessel 260 is maintained to 150° C. or more and under 200° C., preferably at 180° C. as a substrate loading temperature by a temperature control of the heater 206 by the temperature controller 238.

Note that in this step, in order to discharge the residual gas in the reaction vessel 260, the inactive gas such as N₂ may be supplied to the gas supply pipe 232, and may be flown to the reaction vessel 260 from the gas inlet port of the nozzle 230 as purge gas.

When the temperature and the pressure in the reaction vessel 260 are stabilized, the boat 217 is inserted into the processing chamber 201 by the elevation of the boat elevator 115.

When loading of the boat 217 into the processing chamber 201 is finished, the temperature increasing step of the reaction vessel 260 is executed.

In the boat loading step, as the temperature in the reaction vessel 260 is set higher, a natural oxide is easily formed on the substrate before film formation. Namely, as the temperature in the reaction vessel 260 is set higher as a substrate loading temperature, even if a natural oxide film removing step is provided thereafter, the natural oxide film can be hardly removed, thus requiring much time for removing the natural oxide film.

Therefore, by setting the temperature in the reaction vessel 260 lower as much as possible in the boat loading step, it is possible to make the natural oxide film hardly formed on the substrate, and an extra step can be eliminated.

### <Temperature Increasing Step of the Reaction Vessel>

In the temperature increasing step, the temperature of the reaction vessel 260 is increased from 180° C. to 750° C. which is a processing temperature, by a temperature control of the heater 206, to execute the film forming step.

When the temperature in the reaction vessel 260 is stabilized and the pressure is stabilized to the pressure suitable for forming the thin film which is formed, the film forming step of the substrate 200 is executed.

At this time, the power supply condition to the heater 206 is feedback-controlled by the temperature controller 238, so that the inside of the reaction vessel is set in a desired temperature distribution based on temperature information detected by the temperature sensor 263.

Subsequently, by rotating the boat 217 by the rotation mechanism 254, the substrate 200 is rotated. When the temperature and pressure of the reaction vessel 260 are stabilized to the temperature (750° C.) and pressure suitable for the thin film respectively, the film forming step of the substrate is executed.

### <Film Forming Step>

In order to form an Si₃N₄ film on the substrate 200, being a silicon wafer in the film forming step, the temperature of the reaction vessel 260 is maintained to 750° C. which is the processing temperature by the temperature control of the heater 206, and the source gas (DCS and NH3) is supplied from the source gas supply source.

The flow rate of the source gas is feedback-controlled so as to be a desired flow rate by the MFC 241. When the source gas is introduced to the nozzle 230 from the gas supply pipe 232 and is introduced into the reaction vessel 260 form the gas supply port of the nozzle 230, the source gas drifts up in the reaction vessel 260 and thereafter is flown to the cylindrical space 250 from the upper end opening of the inner tube 204 and is exhausted from the exhaust tube 231. Then, when passing through the processing chamber 201, the source gas is brought into contact with the surface of the substrate 200 and is deposited on the surface of the substrate 200 by the thermal CVD reaction.

When the thin film such as the Poly Si film is formed on the substrate 200, being the silicon wafer, as described above, the film forming gas (SiH₄) is supplied from the nozzle 230.

When previously set processing time is elapsed and the thin film is formed on the surface of the substrate 200, supply of the source gas to the gas supply pipe 232 is intercepted.

### <Temperature Decreasing Step in the Reaction Vessel>

In this step, the residual gas is exhausted by the vacuum exhaust device 246, while the temperature of the reaction vessel 260 is gradually decreased from 750° C., being the processing temperature, to 550° C. by the temperature control of the heater 206. At this time, the inert gas from the inert gas supply source is supplied to the gas supply pipe 232, and the atmosphere in the reaction vessel 260 is replaced with an inert gas atmosphere by the inert gas introduced from the nozzle 230. When the replacement is finished and the pressure is recovered to a normal pressure, the purge gas (inert gas) is introduced to the reaction vessel and a reaction by-product as the deposit remained in the reaction vessel 260 may be exhausted.

When the temperature in the reaction vessel 260 is stabilized to the temperature higher than 500° C., being the first temperature, such as 550° C., the processing is moved to the boat unloading step.

### <Boat Unloading, Substrate Discharging, and Loading Step of Empty Boat>

In this step, the boat 217 is unloaded from the processing chamber 201 by lowering of the boat elevator 115 at 550° C., being a substrate unloading temperature, and the already processed substrate 200 after completing film formation is taken out from the boat 217. Then, all processed substrates 200 are taken out and thereafter the empty boat 217 is inserted into the processing chamber 201 by elevating the boat elevator. When the seal cap 219 and the O-ring 220b air-tightly close the reaction vessel 260, boat unloading, substrate discharging, and unloading step of the empty boat 217 are finished, and the first cleaning step (high temperature cleaning step) is executed.

Note that in the boat unloading step, even if the natural oxide film is formed on the substrate, by providing the natural oxide film removing step in the later step, an influence by the natural oxide film can be suppressed. In addition, in a case of a D(doped)-Poly Si film, the natural oxide film is intentionally formed in some cases in the boat unloading step. Therefore, the influence by the natural oxide film is smaller in the boat unloading step, compared to the boat loading step. Therefore, in the boat unloading step, the inside of the reaction vessel may be maintained to high temperature.

### <First Cleaning Step (High Temperature Cleaning Step)>

In this first cleaning step, the cleaning gas is supplied to the gas supply pipe 232 form the cleaning gas supply source.

Then, by introducing the cleaning gas to the reaction vessel 260 form the gas supply port of the nozzle 230, the deposit deposited on the inner surface of the reaction vessel or the surface of the component arranged in the reaction vessel is subjected to etching.

At this time, the volume concentration (first volume concentration) of the cleaning gas as the etching gas is adjusted to 1 vol % or more and under 10 vol %, with respect to the dilution gas (inert gas).

When the volume concentration of the cleaning gas becomes 1 vol % or more and under 10 vol %, as is explained in the embodiment 1 (second cleaning method), an etching amount can be controlled by adjusting the cleaning processing time even if the temperature of the reaction vessel 260 is set at 550° C., being a high temperature.

The etching processing time is decided to be at least half or more of a total thickness and under the total thickness, such as around 90% of the deposit based on the etching rate of the cleaning gas at 550° C. and an original thickness of the deposit deposited on the inner wall of the reaction vessel 260 or the component arranged in the reaction vessel before cleaning.

When the cleaning processing time is finished, supply of the cleaning gas to the gas supply pipe 232 from the cleaning gas supply source is immediately stopped or intercepted.

Accordingly, in this embodiment 2 also, it is possible to suppress the damage on the inner wall of the reaction vessel 260 and the surface of the component set in the reaction vessel. Therefore, by an etching rate-oriented dry cleaning, at least half or more and under the total thickness of the deposit, such as around 90% of the deposit is removed by the etching of the cleaning gas.

### <Temperature Decreasing Step in the Reaction Vessel>

When the first cleaning step is finished, in order to remove the residual film of the deposit in the second cleaning step subsequent to the first cleaning step, the controller executes a temperature decreasing process of the reaction vessel 260. In this step, the temperature in the reaction vessel 260 is decreased from 550° C. to 150° C. or more, under 200° C., and preferably to 180° C. At this time, the atmosphere in the reaction vessel 260 may be exhausted by supplying the inert gas of the inert gas supply source to the gas supply pipe 232 and introducing it from the nozzle 230.

### <Second Cleaning Step (Low Temperature Cleaning Step)>

In the second cleaning step, the temperature in the reaction vessel 260 is maintained to a prescribed temperature in a temperature range from 550° C. to 150° C. or more and under 200° C., preferably to 180° C., the cleaning gas is supplied to the gas supply pipe 232 from the cleaning gas supply source and the cleaning gas is supplied to the reaction vessel 260 from the gas supply port of the nozzle 230.

At this time, the volume concentration (second volume concentration) of the cleaning gas with respect to the inert gas as the dilution gas is set in a range from 10 vol % or more which is higher than the volume concentration of the first cleaning step to under 30 vol %, and is adjusted to be 25 vol % or more and under 30 vol %.

Then, the cleaning processing time is calculated based on the etching rate of the cleaning gas at a prescribed temperature in the temperature range from 150° C. or more and under 200° C., such as 180° C., and the thickness of the residual film of the cleaning gas, and the cleaning gas is introduced to the reaction vessel 260 during this cleaning time.

In this case, similarly to the embodiment 1, by gradually increasing the volume concentration of the cleaning gas, gradually increasing the gas partial pressure, and gradually increasing a gas total pressure, the controllability of the etching rate (removing speed) can be improved. Particularly, the etching rate can not be operated as expected in some cases, only by the control of the etching rate by temperature variation. For example, when the temperature becomes relatively low such as the substrate loading temperature like 100° C. to 150° C. at the time of loading the substrate in the next thin film forming step, the etching rate is sometimes excessively lower than expected. Therefore, by using a parameter such as the volume concentration and pressure, it is possible to easily control the etching rate as expected so as to increase the excessively low etching rate.

When the second cleaning step is finished, the supply of the cleaning gas to the gas supply pipe 232 from the cleaning gas supply source is immediately stopped or intercepted to finish the second cleaning step.

### <Purging Step>

In this step, the reaction product vaporized in the first cleaning step and the second cleaning step is exhausted in a state of gas. Therefore, by the temperature control of the heater 206, the temperature of the reaction vessel 260 is maintained to a vaporized temperature or more of the deposit, such as 180° C., and in this state, the inert gas, for example N₂ gas is supplied to the gas supply pipe 232 as the purge gas while the atmosphere in the reaction vessel is exhausted by the vacuum exhaust device 246, and is introduced into the reaction vessel 260 from the nozzle 230.

When the inside of the reaction vessel 260 is maintained to 180° C., and the inert gas such as the N2 gas is introduced as the purge gas, the reaction gas of the deposit generated by etching in the reaction vessel 260 is totally exhausted to the exhaust tube 231, and is captured by an exhaust trap interposed in the exhaust tube 231.

Note that after recovery by the exhaust trap, the reaction gas is made to be harmless by a removing device not shown provided on the upper stream side of the vacuum exhaust device 246.

Thus, in this embodiment 2, in the first cleaning step (high temperature cleaning), the cleaning gas (ClF₃) is flown under the high temperature such as 550° C. or more and under 600° C. as the temperature in the reaction vessel 260, to increase the etching rate of the cleaning gas, and the film of the deposit deposited on the inner wall of the reaction vessel 260 constituted of an Si-containing member such as quartz and SiC and a metal, and the surface of the component in the reaction vessel is subjected to etching at a high etching speed to an etching amount not allowing the surface (boundary surface with the deposit) of the quartz, etc, to appear. Then, thereafter in the second cleaning step (low temperature cleaning step), the temperature in the reaction vessel is lowered to under 200° C. and 150° C. or more to set the etching rate low, and thereafter the cleaning gas (ClF₃) is flown and the residual film is subjected to etching.

Namely, the etching speed is increase in the first cleaning step, to perform etching first so as not allow the boundary surface with the deposit to be exposed, and thereafter the temperature in the reaction vessel 260 is set low to be the temperature in a range of 150° C. or more and under 200° C. to make the etching rate low, and the residual film deposited on the surface of the reaction vessel 260, etc, is subjected to etching at a low speed. Namely, the residual film is subjected to etching while the surface of the material constituting the inner wall of the reaction vessel 260 and the component arranged in the reaction vessel are prevented from being subjected to etching.

In addition, by slowing the etching rate of the residual film, etching control can be finely controlled, thus making it easy to perform the etching control of only the deposit whereby the reaction vessel 260 and the surface of the material constituting the component in the reaction vessel 260 are not influenced, when the surface is constituted of the quartz or the Si-containing material such as SiC.

Thus, the etching time can be shortened, and the temperature of the reaction vessel 260 can be made close to the boat loading temperature of the next batch processing effectively, thus improving throughput.

Further, extremely low boat loading temperature makes it possible to eliminate a temperature difference between substrate surfaces at the time of boat loading, namely between each of the plurality of substrates 200 placed on the boat 217, and the temperature difference in the boat 217, and an inter-surface thermal history becomes uniform.

### Embodiment 3

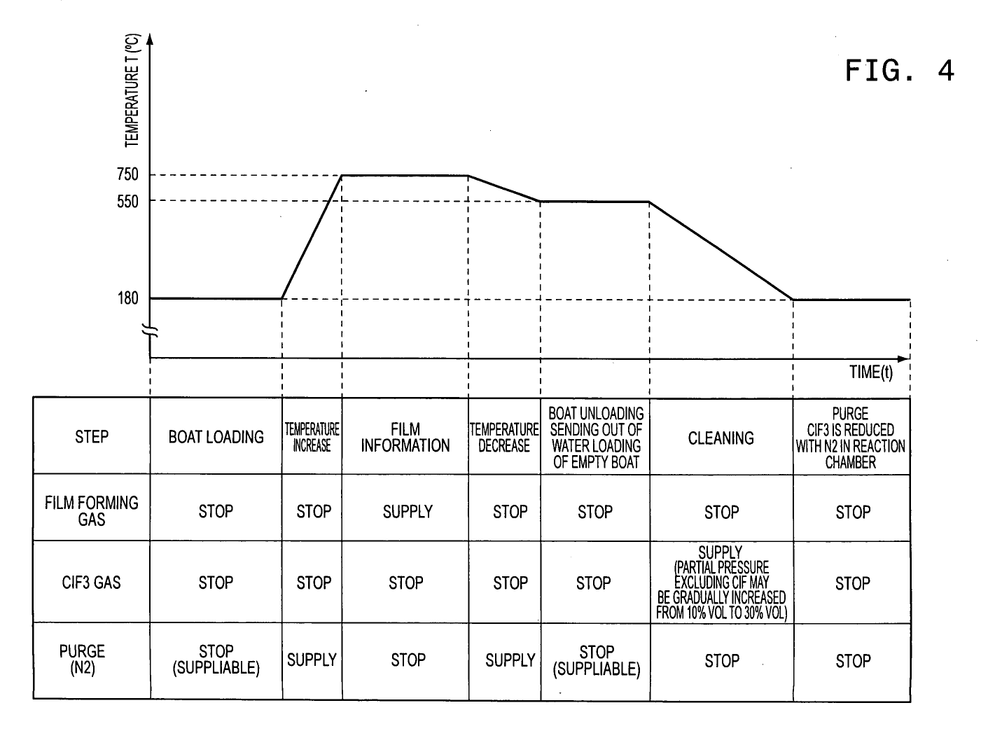

FIG. 4 shows the manufacturing step of the semiconductor device according to a third embodiment.

In this embodiment also, similarly to the embodiment 1, the dry cleaning step for removing the film of the deposit is executed between this step and the next thin film forming step, after the film forming step is repeated once or a plurality of times. In addition, in the dry cleaning step, the cleaning gas similar to that of the embodiment 1 is used, and for example, the ClF₃ gas or the cleaning gas containing fluorine (F) is used, and the inert gas such as N₂, Ar, He is used as the dilution gas of the cleaning gas.

In this example, the boat loading step, the temperature increasing step in the reaction vessel, the film forming step, the boat unloading, the substrate discharging and inserting step of the empty boat 217, the cleaning step, and the purging step of the reaction vessel are sequentially executed. Note that in this embodiment 3, the boat loading step, the temperature increasing step in the reaction vessel, the film forming step, the temperature decreasing step in the reaction vessel, and the purging step are same as those of the embodiment 2, and therefore the cleaning step will be described in detail here.

### <Cleaning Step>

In the cleaning step, the temperature in the reaction vessel 260 is gradually decreased to 180° C. from 550° C. by the temperature control of the heater 206. Then, during the cleaning processing time defined by the temperature decreasing process from 550° C. to just before 180° C., the cleaning gas is introduced. The time required for setting the total thickness of the deposit as a target etching amount is decided as the cleaning processing time, based on the original thickness of the deposit before cleaning, namely before etching. In this case, preferably the etching rate of the cleaning gas is corrected, with the volume concentration of the cleaning gas set at under 10 vol % at 550° C., preferably at 1 vol % or more and under 5 vol %, and at 30 vol % at the temperature just before 180° C., and the over etching is prevented.

Note that during temperature decrease, the volume concentration of the cleaning gas may be gradually increased. In addition, during the temperature decrease, the gas partial pressure may be gradually increased or the gas total pressure may be gradually increased. Thus, it is possible to improve the controllability of the removing speed, namely the etching rate.

Thus, in the embodiment 3, the temperature in the reaction vessel 260 is decreased from the processing temperature to be under 500 to 600° C., being the substrate unloading temperature, and the boat unloading step is completed. Thereafter, subsequently the cleaning gas (ClF₃(chlorine trifluoride)) gas is continuously introduced while the temperature in the reaction vessel 260 is gradually decreased in a range from 550° C. or more to under 600° C., to 150 or more to under 200° C.

Thus, the effect explained in the embodiments 1 and 2 and one or more effects explained hereunder are exhibited. Since the etching rate which is high under the high temperature is lowered little by little as the temperature is decreased. Therefore, the film of the deposit deposited on the reaction vessel 260 and the surface of the component in the reaction vessel 260 is subjected to etching at a high speed first, and can be subjected to etching at a low speed little by little, when being placed closer to the surface such as a wall surface of the reaction vessel 260. Thus, the residual film of the deposit can be subjected to etching, while preventing etching of the surface such as the inner wall of the reaction vessel 260.

Namely, by slowing the etching rate of the residual film of the deposit, the etching can be finely controlled, thus making it easy to control the etching of only the deposit whereby the surface of the material constituting the inner wall, etc, of the reaction vessel 260 is not influenced. Accordingly, even when the quartz or SiC is used in the inner surface of the reaction vessel or the component arranged in the reaction vessel such as the boat 217, the damage of the surface by etching can be suppressed. In addition, whereby the etching time can be shortened, and the temperature in the reaction vessel 20 can be set efficiently close to the substrate loading temperature of the next batch. In addition, it is not necessary to provide the temperature decreasing step as described in the embodiments 1 and 2, separately from the cleaning step. For this reason, the throughput is improved.

### Embodiment 4

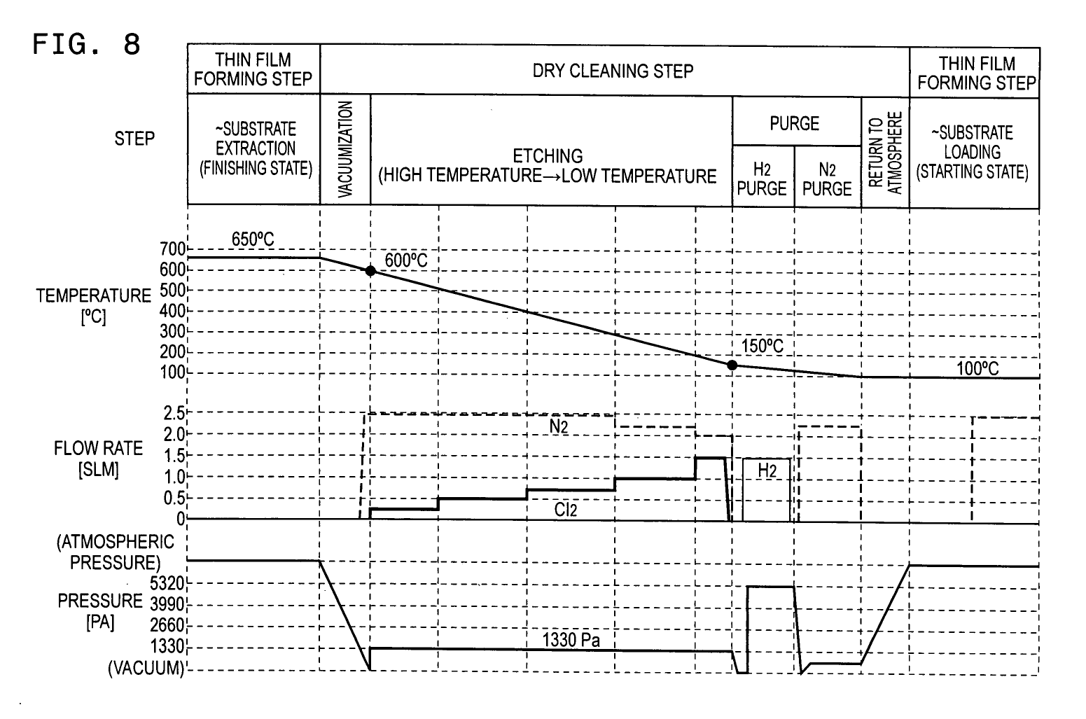

FIG. 8 shows the manufacturing step of the semiconductor device according to a fourth embodiment.

In this embodiment also, similarly to the embodiment 1, the film forming step is repeated once or a plurality of times, and thereafter the dry cleaning step is executed between this step and the next thin film forming step. Moreover, in the dry cleaning step, the cleaning gas similar to that of the embodiment 1 is used, and for example, the cleaning gas containing the ClF₃ gas or fluorine (F) is used, and as the dilution gas of the cleaning gas, the inert gas such as N₂, Ar, and He is used.

In this example, the boat loading step, the temperature increasing step in the reaction vessel, the film forming step, the boat unloading step, the vacuumization step, the cleaning step for performing etching, and the purging step of the inside of the reaction vessel are sequentially executed. Note that in this embodiment 4, the temperature increasing step in the reaction vessel, the film forming step, and the boat unloading step are the same as those of the embodiment 1, and a point of lowering the temperature of the reaction vessel is the same as that of the embodiments 2 and 3, and the vacuumization step, the etching step, and the purging step of the inside of the reaction vessel are described here in detail.

### <Vacuumization Step>

In the vacuumization step, the atmosphere in the reaction vessel 260 is exhausted, while the temperature is decreased from 650° C., being the substrate unloading temperature, to 600° C., being a cleaning step starting temperature. When the temperature becomes in the vicinity of 600° C., being the cleaning step starting temperature, the pressure of the reaction vessel 260 is set in vacuum (in the vicinity of OPa to 5 Pa).

### <Cleaning Step>

In the cleaning step, during the etching processing time defined by the time required for decreasing the temperature to the temperature just before 150° C., being the cleaning step finishing temperature, from 600° C., being the substrate unloading temperature. Note that chlorine (Cl₂) gas is used as the cleaning gas. As described in the embodiment 1, the chlorine (Cl₂) gas has the characteristic of etching silicon (Si) and not etching oxide film and quartz (SiO₂), and therefore etching selectivity with the deposit and quartz, being the material of the inner tube 204 is excellent, thus reducing the damage applied on the inner wall of the quartz in the reaction vessel 260 by etching.

Note that the etching step finishing temperature is set at the temperature just before 150° C. However, if the total thickness of the deposit can be etched, the cleaning step finishing temperature is not limited to this temperature.

Similarly to the embodiment 3, as the cleaning processing time, the time required for setting the total thickness of the deposit as the target etching amount is decided, based on the etching rate of the cleaning gas at each temperature in temperature decrease and the thickness of the deposit before etching.

In FIG. 8, in the cleaning step of the embodiment 4, the temperature in the reaction vessel 260 is gradually decreased from 600° C. to 150° C. by the temperature control of the heater 206. Then, the cleaning gas is introduced during the cleaning processing time defined by the temperature decreasing process from 600° C. to just before 150° C. At this time, the pressure in the reaction vessel is maintained to 1330 Pa, being a reduced pressure state.

Note that the volume concentration of the cleaning gas may be gradually increased while the temperature is decreased. In addition, in this case, the gas partial pressure may be gradually increased or the gas total pressure may be gradually increased during temperature decrease. Thus, the controllability of the removing speed, namely the etching rate can be improved.

Thus, as described in the embodiment 3, the residual film of the deposit can be subjected to etching, while preventing etching of the surface of the inner wall, etc, of the reaction vessel 260.

In addition, it is possible to shorten the etching time, and setting the temperature in the reaction vessel 20 efficiently close to the substrate loading temperature of the next batch. Further, it is not necessary for providing the temperature decreasing step separately from the cleaning step. For this reason, the throughput is improved. Accordingly, even when the quartz and SiC are used in the inner surface of the reaction vessel or the component arranged in the reaction vessel such as the boat 217, the damage of the surface due to etching can be suppressed.

In FIG. 8, in the cleaning step of the embodiment 4, the flow rate of the Cl2 gas is increased discontinuously or stepwise while the temperature is decreased. However, if the etching rate can be adjusted, the Cl2 gas is not limited to be changed discontinuously, specifically increased discontinuously, for example stepwise, but may be increase gradually.

In addition, in this step, the Cl₂ gas is diluted with N₂ gas, being the inert gas, and the total pressure is set to be constant. However, if the etching rate can be adjusted, the N₂ gas is not limited to be changed discontinuously, specifically reduced discontinuously, for example stepwise, but may be reduced gradually.

### <First Purging Step (H2 Purge)>

When the cleaning step (high temperature cleaning step) is finished, the supply of the inert gas (N₂) as the cleaning gas (Cl₂) and the dilution gas to the gas supply pipe 231 is immediately stopped or intercepted. Thereafter, H2 gas is supplied into the reaction vessel 260 from a hydrogen gas supply source 273 via a hydrogen gas supply line 283, while temperature decrease is continued. At this time, the pressure in the reaction vessel is maintained to 5320 Pa, being the reduced pressure state. Thus, the cleaning gas (Cl₂) and the H₂ gas are reacted, and a hydrogen chloride gas (HCl) is generated. By this reaction, the cleaning gas (Cl₂) remained in the reaction vessel 260 can be efficiently removed, and the hydrogen chloride gas is exhausted form the exhaust tube 231.

In the embodiment 4, the first purging step is executed while the temperature is decreased from 150° C. to 120° C. However, this range is not limited thereto, if the reaction is properly performed.

### <Second Purging Step (N₂ Purge)>

When the first purging step is finished, the supply of the H₂ gas is immediately stopped or intercepted. Thereafter, the N2 gas is supplied into the reaction vessel 260 again while decreasing the temperature to 100° C., being the substrate loading temperature, and the remained H₂ is exhausted. Thus, cleaning of the reaction vessel 260 is achieved.

Note that the total pressure in the second purging step is set to be constant. This is because in the second purging step, the inside of the reaction vessel 260 is exhausted so that the pressure is reduced, so that the total pressure is not fluctuated. Although it is preferable to perform purging step in this way, the total pressure may be set to be higher, provided that the purging step can be appropriately performed.

The throughput can be improved by performing first and second purging steps before an atmospheric pressure returning step after cleaning.

### <Atmospheric Pressure Returning Step (Starting State)>

In this step, the temperature in the reaction vessel 260 is maintained to 100° C., being the substrate loading temperature, and the processing is finished at the time point when the pressure is returned to the atmospheric pressure by exhaust.

When this step is finished, the previously explained thin film forming step is started as the next batch processing.

By this embodiment, one or more effects out of the effects explained in the embodiments 1 to 3 and the effects explained hereunder can be exhibited.

By supplying the cleaning gas into the reaction vessel while decreasing the temperature in the reaction vessel, and removing the deposit deposited on the inner wall of the reaction vessel, the removing speed is set large at the time of high temperature in the reaction vessel to enable rough machining to be performed to remove the deposit, and as the temperature is lowered, the removing speed is gradually set small, to finely removed the deposit. Namely, by decreasing the temperature, the etching rate for removing the deposit can be adjusted to an optimal rate.

In addition, film formation is performed by setting the temperature in the reaction vessel at a processing temperature, and the substrate after film formation is unloaded from the reaction vessel by setting the inside of the reaction vessel at the substrate unloading temperature under the processing temperature. Whereby, the temperature is lowered even in a period from the film forming step to the substrate unloading step, thus making it possible to adjust the etching rate to an optimal rate.

In addition, by loading the substrate into the reaction vessel by setting the inside of the reaction vessel at the substrate loading temperature, forming the film by setting the inside of this reaction vessel at the processing temperature, then unloading the substrate after film formation from the reaction vessel by setting the inside of the reaction vessel at the substrate unloading temperature, and in the removing step, by decreasing the temperature of the inside of the reaction vessel within a range from the substrate unloading temperature to the substrate loading temperature, the processing can be smoothly moved to the next thin film forming step, without increasing the temperature to the substrate loading temperature again.

Note that the cleaning gas can be continued to be supplied while lowering the temperature in the reaction vessel down to the substrate loading temperature from the substrate unloading temperature. Namely, the cleaning gas may be supplied into the reaction vessel, in a substantially entire area while decreasing the temperature in the reaction vessel from the substrate unloading temperature to the substrate loading temperature. In addition, like the temperature decreasing step of the embodiment 1, a part where the cleaning gas is not supplied may be provided.

### ADDITIONAL DESCRIPTION

Preferred embodiments of the present invention will be described hereunder.

### [Description 1]

A manufacturing method of a semiconductor device, comprising the steps of:

loading a substrate into a reaction vessel;

forming a film on the substrate while supplying a film forming gas into the reaction vessel;

unloading the substrate after film formation from the reaction vessel; and

supplying cleaning gas into the reaction vessel while lowering a temperature in the reaction vessel and removing a deposit deposited on at least an inner wall of the reaction vessel in the film forming step.

### [Description 2]

A manufacturing method of a semiconductor device, comprising the steps of:

loading a substrate into a reaction vessel;

forming a film on the substrate while supplying a film forming gas into the reaction vessel, with an inside of the reaction vessel set at a processing temperature;

unloading the substrate after film formation from the reaction vessel, with the inside of the reaction vessel set at a substrate unloading temperature of the processing temperature or less; and

supplying a cleaning gas into the reaction vessel while lowering the temperature in the reaction vessel from the substrate unloading temperature, and removing a deposit deposited on at least an inner wall of the reaction vessel in the film forming step.

### [Description 3]

The manufacturing method of the semiconductor device according to description 1, wherein in the removing step, the cleaning gas is supplied into the reaction vessel while lowering the temperature in the reaction vessel in a range from the temperature in the reaction vessel in the loading step to the temperature in the reaction vessel in the unloading step.

### [Description 4]

The manufacturing method of the semiconductor device according to description 1, wherein the cleaning gas is supplied into the reaction vessel so that a volume concentration of the cleaning gas in the reaction vessel is set to be 1 vol % or more and under 10 vol % in the removing step.

### [Description 5]

The manufacturing method of the semiconductor device according to description 3, wherein the cleaning gas is supplied into the reaction vessel, in a substantially entire area while lowering the temperature in the reaction vessel from the substrate unloading temperature to the substrate loading temperature in the removing step.

### [Description 6]

The manufacturing method of the semiconductor device according to description 1, wherein a volume concentration of the cleaning gas in the reaction vessel is set to be gradually higher in the removing step.

### [Description 7]

The manufacturing method of the semiconductor device according to description 1, wherein a gas partial pressure of the cleaning gas in the reaction vessel is set to be gradually higher in the removing step.

### [Description 8]

The manufacturing method of the semiconductor device according to description 1, wherein a gas total pressure of the cleaning gas in the reaction vessel is set to be gradually higher in the removing step.

### [Description 9]

The manufacturing method of the semiconductor device according to description 1, wherein the cleaning gas is a gas containing one or more of Cl₂, ClF₃, F₂, and HF.

[Description 10]

A manufacturing method of a semiconductor device, comprising the steps of:

loading a substrate into a reaction vessel;

forming a film on the substrate while supplying a film forming gas into the reaction vessel;

unloading the substrate after film formation from the reaction vessel;

supplying cleaning gas into the reaction vessel while lowering a temperature in the reaction vessel, with the film forming step having a first removing step of removing a deposit deposited on at least an inner wall of the reaction vessel and a second removing step of supplying the cleaning gas into the reaction vessel, with a temperature in the reaction vessel set to be lower than the temperature in the first removing step, and removing at least the deposit remained in the reaction vessel in the first removing step.

### [Description 11]

The manufacturing method of the semiconductor device according to description 10, wherein the cleaning gas is supplied into the reaction vessel, so that a volume concentration of the cleaning gas in the reaction vessel is set to be 1 vol % or more and under 10 vol % in the first removing step.

### [Description 12]

The manufacturing method of the semiconductor device according to description 10, wherein a volume concentration of the cleaning gas in the reaction vessel in the second removing step is higher than a gas volume concentration in the first removing step.

### [Description 13]

The manufacturing method of the semiconductor device according to description 10, wherein a volume concentration of the cleaning gas in the reaction vessel is gradually set to be high in the first removing step.

### [Description 14]

The manufacturing method of the semiconductor device according to description 10, wherein a gas partial pressure of the cleaning gas in the reaction vessel is gradually set to be high in the first removing step.

### [Description 15]

The manufacturing method of the semiconductor device according to description 10, wherein a gas total pressure of the cleaning gas in the reaction vessel is gradually set to be high in the first removing step.

### [Description 16]

The manufacturing method of the semiconductor device according to description 10, wherein the cleaning gas is a gas containing any one of Cl₂, ClF₃, F₂, and HF in the first and second removing steps.

### [Description 17]

A substrate processing apparatus, comprising:

a reaction vessel that processes a substrate;

a heating device that heats an inside of the reaction vessel;

a film forming gas supply line that supplies film forming gas into the reaction vessel;

a cleaning gas supply line that supplies cleaning gas into the reaction vessel;

a gas supply amount controller disposed in the cleaning gas supply line, for controlling a supply amount of the cleaning gas;

a heating controller that controls the heating device;

an exhaust line that exhausts the inside of the reaction vessel; and

a controller that controls at least the heating device and the gas supply amount controller, so as to supply the cleaning gas from the cleaning gas supply line into the reaction vessel while lowering a temperature in the reaction vessel.

### [Description 18]

The substrate processing apparatus according to description 17, wherein the controller controls at least the heating device and the gas supply amount controller, so as to supply the cleaning gas into the reaction vessel from the cleaning gas supply line while lowering the temperature in the reaction vessel in a range from a substrate unloading temperature to a substrate loading temperature.

[Description 19]

A substrate processing apparatus, comprising:

a reaction vessel that processes a substrate;

a heating device that heats an inside of the reaction vessel;

a film forming gas supply line that supplies film forming gas into the reaction vessel;

a cleaning gas supply line that supplies cleaning gas into the reaction vessel;

a gas supply amount controller disposed in the cleaning gas supply line, for controlling a supply amount of the cleaning gas;

a heating controller that controls the heating device;

an exhaust line that exhausts the inside of the reaction vessel; and

a controller that controls at least the heating device and the gas supply amount controller, so as to supply the cleaning gas into the reaction vessel from the cleaning gas supply line, while lowering a temperature in the reaction vessel from a substrate unloading temperature.

### [Description 20]

A substrate processing apparatus, comprising:

a reaction vessel that processes a substrate;

a heating device that heats an inside of the reaction vessel;

a film forming gas supply line that supplies film forming gas into the reaction vessel;

a cleaning gas supply line that supplies cleaning gas into the reaction vessel;

a gas supply amount controller disposed in the cleaning gas supply line, for controlling a supply amount of the cleaning gas;

a heating controller that controls the heating device;

an exhaust line that exhausts the inside of the reaction vessel; and

a controller that controls at least the heating device and the gas supply amount controller, so as to supply the cleaning gas into the reaction vessel from the cleaning gas supply lined, while lowering the temperature in the reaction vessel from a substrate unloading temperature.

### [Description 20]

A substrate processing apparatus, comprising:

a reaction vessel that processes a substrate;

a heating device that heats an inside of the reaction vessel;

a film forming gas supply line that supplies film forming gas into the reaction vessel;

a cleaning gas supply line that supplies cleaning gas into the reaction vessel;

a gas supply amount controller disposed in the cleaning gas supply line, for controlling a supply amount of the cleaning gas;

a heating controller that controls the heating device;

an exhaust line that exhausts the inside of the reaction vessel; and

a controller that controls at least the heating device and the gas supply amount controller, so as to supply the cleaning gas into the reaction vessel from the cleaning gas supply line while lowering the temperature in the reaction vessel in a range from a substrate unloading temperature to a substrate loading temperature.

### [Description 21]

A manufacturing method of a semiconductor device, comprising the steps of:

loading the substrate into a reaction vessel, with a temperature in the reaction vessel set at a substrate loading temperature;

forming a film on the substrate while supplying film forming gas into the reaction vessel, with the inside of the reaction vessel set at a processing temperature;

unloading the substrate after film formation from the reaction vessel, with the inside of the reaction vessel set at a substrate unloading temperature; and

supplying cleaning gas into the reaction vessel while lowering the temperature in the reaction vessel in a range from the substrate unloading temperature to the substrate loading temperature, and removing a deposit deposited on at least the inner wall of the reaction vessel in the film forming step.

What is claimed is:

1. A manufacturing method of a semiconductor device, comprising the steps of:
loading a substrate into a reaction vessel;
forming a film on the substrate while supplying a film forming gas into the reaction vessel;
unloading the substrate after film formation from the reaction vessel; and
supplying cleaning gas into the reaction vessel while lowering a temperature in the reaction vessel and removing a deposit deposited on at least an inner wall of the reaction vessel in the film forming step.

2. The manufacturing method of the semiconductor device according to claim 1, wherein cleaning gas is supplied into the reaction vessel while lowering a temperature in the reaction vessel in a range from the temperature in the reaction vessel in the loading step to the temperature in the reaction vessel in the unloading step, and removing a deposit deposited on at least the inner wall of the reaction vessel in the film forming step.

3. The manufacturing method of the semiconductor device according to claim 1, wherein the cleaning gas is supplied into the reaction vessel, so that a volume concentration of the cleaning gas in the reaction vessel is set to be 1 vol % or more and under 10 vol %.

4. The manufacturing method of the semiconductor device according to claim 2, wherein the cleaning gas is supplied into the reaction vessel, in a substantially entire area while lowering a temperature in the reaction vessel from the substrate unloading temperature to the substrate loading temperature, in the removing step.

5. The manufacturing method of the semiconductor device according to claim 1, wherein a volume concentration of the cleaning gas in the reaction vessel is gradually set to be high in the removing step.

6. The manufacturing method of the semiconductor device according to claim 1, wherein a gas partial pressure of the cleaning gas in the reaction vessel is gradually set to be high in the removing step.

7. The manufacturing method of the semiconductor device according to claim 1, wherein a gas total pressure of the cleaning gas in the reaction vessel is gradually set to be high in the removing step.

8. The manufacturing method of the semiconductor device according to claim 1, wherein the cleaning gas contains any one of Cl₂, ClF₃, F₂, and HF in the removing step.

9. A manufacturing method of a semiconductor device, comprising the steps of:
loading a substrate into a reaction vessel;
forming a film on the substrate while supplying a film forming gas into the reaction vessel;
unloading the substrate after film formation from the reaction vessel;
supplying cleaning gas into the reaction vessel while lowering a temperature in the reaction vessel, with the film forming step having a first removing step of removing a deposit deposited on at least an inner wall of the reaction vessel and a second removing step of supplying the cleaning gas into the reaction vessel, with a temperature in the reaction vessel set to be lower than the temperature in the first removing step, and removing at least the deposit remained in the reaction vessel in the first removing step.

10. The manufacturing method of the semiconductor device according to claim 9, wherein the cleaning gas is supplied into the reaction vessel, so that a volume concentration of the cleaning gas in the reaction vessel is set to be 1 vol % or more and under 10 vol %.

11. The manufacturing method of the semiconductor device according to claim 9, wherein a volume concentration of the cleaning gas in the reaction vessel in the second removing step is higher than a gas volume concentration in the first removing step.

12. The manufacturing method of the semiconductor device according to claim 9, wherein a volume concentration of the cleaning gas in the reaction vessel is gradually set to be high in the first removing step.

13. The manufacturing method of the semiconductor device according to claim 9, wherein a gas partial pressure of the cleaning gas in the reaction vessel is gradually set to be high in the first removing step.

14. The manufacturing method of the semiconductor device according to claim 9, wherein a gas total pressure of the cleaning gas in the reaction vessel is gradually set to be high in the first removing step.

15. The manufacturing method of the semiconductor device according to claim 9, wherein the cleaning gas is a gas containing any one of Cl₂, ClF₃, F₂, and HF in the first and second removing steps.

16. A substrate processing apparatus, comprising:
a reaction vessel that processes a substrate;
a heating device that heats an inside of the reaction vessel;
a film forming gas supply line that supplies film forming gas into the reaction vessel;
a cleaning gas supply line that supplies cleaning gas into the reaction vessel;
a gas supply amount controller disposed in the cleaning gas supply line, for controlling a supply amount of the cleaning gas;
a heating controller that controls the heating device;
an exhaust line that exhausts the inside of the reaction vessel; and
a controller that controls at least the heating device and the gas supply amount controller, so as to supply the cleaning gas into the reaction vessel from the cleaning gas supply line, while lowering the temperature in the reaction vessel.

17. A substrate processing apparatus according to claim 16, wherein at least the heating device and the gas supply amount controller are controlled, so as to supply the cleaning gas into the reaction vessel from the cleaning gas supply line while lowering the temperature in the reaction vessel in a range from a substrate unloading temperature to a substrate loading temperature.
